(19) United States
(12) Patent Application Publication
(10) Pub. No.: US 2011/0297718 A1
(43) Pub. Date: Dec. 8, 2011

(54) INFLATABLE DEVICE FOR ADJUSTING THE PROJECTION ANGLE AND/OR HEIGHT OF A VIDEO PROJECTOR

(76) Inventor: Thierry Klein, Bachy (FR)

(21) Appl. No.: 13/012,932

(22) Filed: Jan. 25, 2011

(30) Foreign Application Priority Data
Jan. 25, 2010 (FR) 1050477

(51) Int. Cl. A45C 15/00; F16M 13/00; H05K 7/00

(52) U.S. Cl. 224/575; 248/346.2; 248/346.07

(57) ABSTRACT

The video projection assembly includes a video projector and a device for adjusting the projection angle and/or height of a video projector. The device comprises an inflatable pouch, which can be placed under the video projector, inflating means for inflating said pouch, and deflating means for deflating said pouch, the deflating means being separate from or combined with the inflating means.

### TECHNICAL FIELD

The present invention relates to the field of video projection. Its object is a new device making it possible to adjust the projection angle and/or height of a video projector.

### BACKGROUND OF THE INVENTION

Until now, video projectors have been equipped, at least in part, with legs whereof the height can be adjusted manually and individually, so as to allow adjustment of the projection angle and/or height, once the video projector is positioned on a planar support (table, desk, . . . ).

This manual adjustment of the proper height of each leg is tedious. Moreover, it generally requires that the video projector first be taken out of its case.

### AIM OF THE INVENTION

The present invention aims to propose a new solution for adjusting the projection angle and/or height of a video projector, which makes it possible to simplify that adjustment and make it more practical.

### BRIEF DESCRIPTION OF THE INVENTION

This aim is achieved using a device for adjusting the projection angle and/or height of a video projector, as defined below. This device includes an inflatable pouch, adapted to be placed under a video projector, inflating means for inflating said pouch, and deflating means for deflating said pouch, the deflating means being separate from or combined with the inflating means.

When the pouch is placed under the video projector, it is necessary only to more or less inflate the pouch so as to simply and quickly adjust the projection angle and/or height of the video projector.

More particularly, the device according to the invention can also have the features listed below, considered alone or combined with each other:
The inflatable pouch comprises a part forming a bellows that enables the internal volume of the pouch to increase as it is inflated under pressure.
The inflatable envelope comprises a base plate in relation to which the bellows shaped part can deploy due to the inflation pressure.
The bellows-shaped part is substantially U-shaped when flat.
The device comprises a leverage bag containing the inflatable pouch.
The inflating means is located outside the leverage bag and is connected to the pouch through said bag.
The device comprises a first panel used as the base plate, and a second panel that is mobile relative to the first panel, and in that the position of the second panel relative to the first panel can be adjusted using the inflatable pouch so as to act as a leverage and/or tilting plane of a video projector.
The angle of the second panel relative to the first panel can be adjusted using the inflatable pouch.
The first and second panels are connected to each other by an articulation so as to substantially form a V shape whereof the opening angle can be adjusted using the inflatable pouch.
The first and second panels are connected to each other, on their periphery, and outside said articulation, by a deformable lateral panel with a bellows function.
The first and second panels, and if applicable the deformable lateral panel, constitute panels of the leverage bag.
The device comprises a panel that is mobile and the position of which can be adjusted using the inflatable pouch so as to act as a leverage and/or tilting plane of a video projector.
The inflating means can be removed, completely or partially, from the inflatable pouch so as to allow the pouch to be deflated.
The inflating means include an inflating bulb connected to the inflatable pouch by a hose.
The hose and/or the inflating bulb can be removed from the inflatable pouch, so as to allow the pouch to be deflated.

The invention also relates to a video projection assembly including a video projector and an adjustment device previously cited.

More particularly, the video projection assembly of the invention can also include the features listed below and considered alone or combined with each other:
The inflating device is placed under the video projector.
The assembly includes a carrying case.
The adjusting device is placed inside the carrying case and can be removed from the carrying case.
The adjusting device can be implemented with the video projector by being removed from the carrying case.
The assembly includes fastening means making it possible to fasten the adjusting device to the video projector at least during manipulation or transport of the video projection assembly.
The adjusting device is placed inside the carrying case and is not removable relative to the carrying case.
The adjusting device is placed inside the carrying case, and can be implemented with the video projector without being taken out of the carrying case.

The invention also relates to the use of the aforementioned inflatable adjusting device to adjust the projection angle and/or height of a video projector.

### BRIEF DESCRIPTION OF THE DRAWINGS

Other features and advantages of the invention will emerge upon reading the following detailed description of specific embodiments, provided as a non-limiting and non-exhaustive example of the invention, and in reference to the appended drawings, in which:

FIG. 1 shows a first embodiment of a video projection assembly according to the invention, in the transport configuration,

FIG. 2 shows the video projection assembly of FIG. 2, in the use configuration,

FIG. 3 illustrates one particular embodiment of an inflatable pouch that can be used to adjust the projection angle and/or height of the video projector of the assembly of FIGS. 1 and 2,

FIG. 4 is a flat diagrammatic top view of the inflatable pouch of FIG. 3.

### DETAILED DESCRIPTION OF THE INVENTION

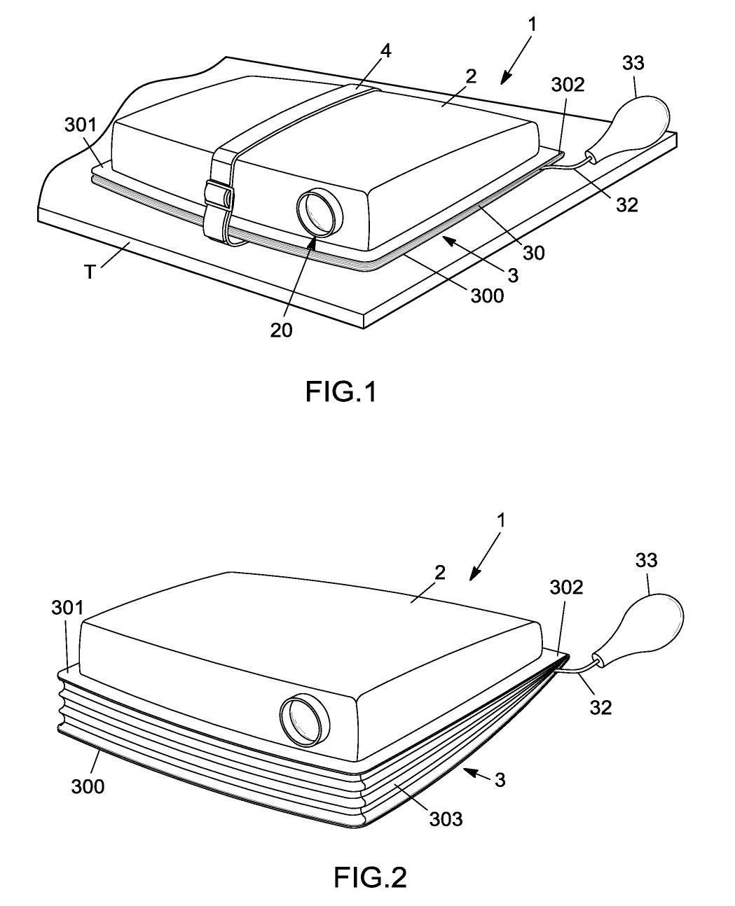

In reference to FIGS. 1 and 2, in one particular alternative embodiment, the video projection assembly 1 according to the invention includes a video projector 2 including optical means 20 for projecting an image on a remote screen (not shown), and a device 3 making it possible to adjust the projection angle and/or height of the video projector 1.

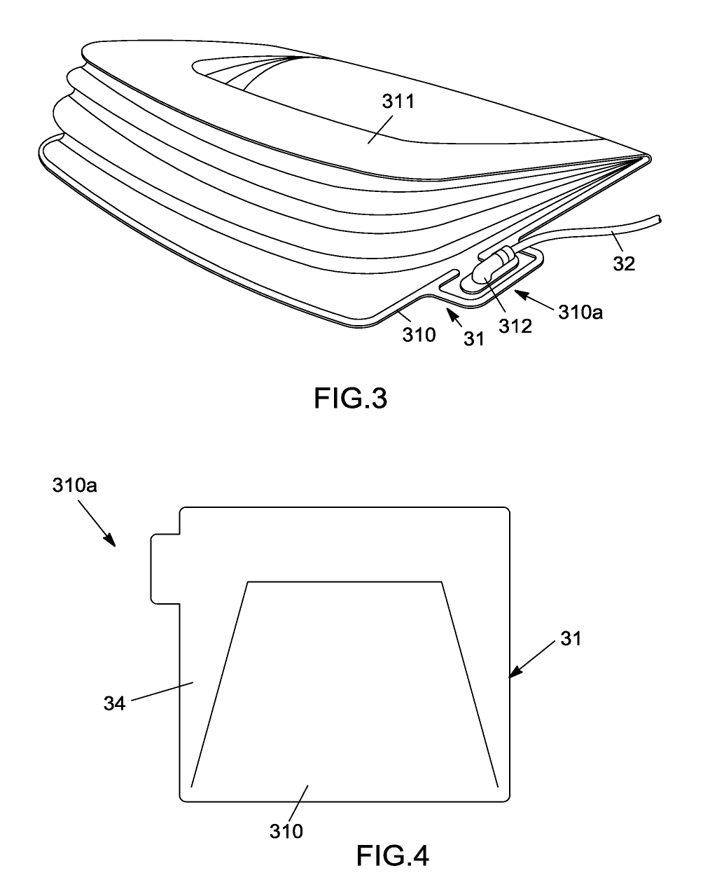

In this particular embodiment, the adjustment device 3 includes a bag 30, containing a separate inflatable pouch, such as that 31 illustrated in FIG. 3, for example.

The bag 30 includes a first panel 300 that is used as a base plate, and a second panel 301 connected to the first panel 300 by an articulation or hinge 302, such that the two panels 300 and 301 substantially form a V having an adjustable opening angle. The first panel 300 and the second panel 301 can be made from a rigid, semi-rigid, or flexible material.

More particularly, the first 300 and second 301 panels are also connected to each other, on their peripheries, and outside said articulation 302, by a deformable lateral panel 303, which acts as a bellows. This deformable lateral panel 303 is for example made from a soft or flexible material and is able to be
folded on itself when the second panel 301 is brought into the configuration of FIG. 1, while being positioned above the panel 300 with an opening angle of the V formed by the two panels 300 and 301 that is substantially null, or
deployed in the configuration of FIG. 2, such that the second panel 301 is spaced away from the first panel 300 and forms, with said first panel 300, a V having a non-null opening angle. When it is completely deployed, the lateral panel 303 makes it possible to limit the maximum opening angle of the V formed by the two panels 300 and 301.

In the particular embodiment of FIGS. 1 and 2, the deformable lateral panel 303 used as a bellows has an accordion structure facilitating its folding on itself. This particular accordion structure is not, however, essential. In another alternative embodiment, the deformable lateral panel 303 used as a bellows can also be made up of a single piece of fabric or something equivalent making it possible to bring the two panels 300 and 301 closer together or to space the two panels 300 and 301 apart.

Housed inside the leverage bag 30 is an inflatable pouch like that 31 of FIG. 3, the structure of which will be described in detail later. This inflatable pouch is connected to a first end of a hose 32 passing through the lateral panel 303 of the bag 30. The other end of the hose 32 is connected to an inflatable bulb 33 placed outside the bag 30.

In reference to FIG. 1, the leverage bag 30 containing the inflatable pouch is placed under the video projector 2 so that the panel 301 is in contact with the lower face of the video projector 2. In FIG. 1, the video projection assembly 1 is in the transport or handling configuration, and the inflatable pouch inside the bag 30 is completely deflated.

More particularly, in this embodiment of FIGS. 1 and 2, the articulation 302 between the two panels 300 and 301 is positioned at the rear portion of the video projector.

Also preferably, the panel 300 in contact with the video projector 1 has a large enough surface area for the entire base of the video projector to be in contact with said leverage panel 300.

More particularly, in the specific embodiment of FIG. 1, the video projection assembly 1 includes a removable fastening means 4, making it possible to temporarily fasten the video projector 2 with the bag 30 so as to facilitate the transport or handling of the video projection assembly 1. More particularly, this fastening means for example includes one or several removable fastening straps 4, or equivalent, with adjustable tightening, and surrounding the video projector 2 and the bag 30.

To implement the video projection assembly 1 of FIG. 1, a user positions that assembly on a planar support T, such as a table, desk, . . . , placing the panel 300 of the bag 30 on said support. Then the user removes, if applicable, the fastening means 4. Then, the user inflates the inflatable pouch housed inside the bag 30 by manually exerting repeated pressure on the inflating bulb 33. The inflation of the pouch makes it possible to increase the volume of said pouch and to apply, on the panel 301 of the bag 30, a mechanical pressure resulting in spacing that panel 301 away from the panel 300, and adjusting the incline of that panel 301 relative to the panel 300. The user thus quickly and very simply adjusts the angle of the video projector 2.

In another alternative embodiment, the bag 30 could be designed so that when the pouch is inflated, the leverage panel 301 move away from the panel 300 acting as a base without altering its orientation relative to the panel 300. In that case, inflating the pouch makes it possible to adjust the height of the video projector relative to the panel 300, due to the height of the video projection.

The user inflates the pouch using the inflation bulb 33 until the inflation pressure is sufficient to obtain the desired angle or height adjustment for the video projector 2. FIG. 2 shows an example of the adjustment of the angle of the video projector 2.

Once the video projection is finished, the user deflates the pouch contained in the bag 30. To that end, the user for example removes the bulb 33 from the hose 32, and manually exerts pressure on the panel 301 to bring it closer to the panel 300 and force the air contained in the pouch to be expelled via the open hose 32. In another embodiment, it is also possible to provide deflating means separate from the inflating means, for example by equipping the inflatable pouch 31 with a deflation valve accessible through the bag 30.

Then, the user secures, if applicable, using the strap 4 or any other equivalent fastening means, the video projector 2 with the bag 30 containing the inflatable pouch in the deflated state (transport configuration of the video projection assembly 1 illustrated in FIG. 1).

FIG. 3 shows a particular inflatable pouch 31 structure that can be housed in the bag 30. In this example, the inflatable pouch 31 includes a base plate 310 on which a portion 311 is fixed that forms an accordion bellows that can deploy relative to the base plate 310 due to the inflation pressure, so as to increase the inner volume of the pouch due to the inflation pressure. More particularly, the bellows-shaped part 311 is substantially U-shaped when flat (FIG. 4).

On one of the sides of the base plate 310, a bent connector 312 is also fixed, one of the ends of which communicates with an air passage opening for inflating/deflating the bellows-shaped part 311 of the pouch 31, and the other end of which is connected to one end of the hose 32.

The invention is not limited to the particular structure of the adjusting device 3 just described in reference to FIGS. 1 to 4. In particular, the video projection assembly of the invention can also include the technical features of the invention listed below, non-exhaustively and non-limitingly.

The video projection assembly can advantageously include a carrying case, able to contain the video projector 2 and the adjusting device 3, for example positioned in the transport configuration of FIG. 1.

In one alternative, the adjusting device 3 can be placed inside a carrying case while being removable therefrom relative to the carrying case. In that case, the adjusting device can be implemented with the video projector 2, as previously explained in reference to FIGS. 1 and 2, being removed with the video projector 2 from the carrying case.

In another alternative, the adjusting device 3 can be placed inside the carrying case, not being removable from the carrying case. In that case, the video projector is used without being taken out of the carrying case.

In another alternative embodiment, the adjusting device 3 may not include a bag 30, the inflatable pouch 31 or equivalent part being used directly to raise the video projector 2, without being housed in a bag.

In another alternative, it is also possible to modify the inflatable pouch so as to insert it between two panels such as the panels 300 and 301, the bellows-shaped part 311 of the pouch 31 replacing the aforementioned deformable lateral part 303 of the bag 30.

1. A device for adjusting the projection angle and/or height of a video projector, said device comprising an inflatable pouch, adapted to be placed under a video projector, inflating means for inflating said pouch, and deflating means for deflating said pouch, the deflating means being separate from or combined with the inflating means.

2. The device according to claim 1, wherein the inflatable pouch comprises a part forming a bellows that enables the internal volume of the pouch to increase as it is inflated under pressure.

3. The device according to claim 2, wherein the inflatable envelope comprises a base plate in relation to which the bellows shaped part can deploy due to the inflation pressure.

4. The device according to claim 2, wherein the bellows-shaped part is substantially U-shaped when flat.

5. The device according to claim 1, further comprising a leverage bag containing the inflatable pouch.

6. The device according to claim 5, wherein the inflating means is located outside the leverage bag and is connected to the pouch through said bag.

7. The device according to claim 1, further comprising a first panel used as the base plate, and a second panel that is mobile relative to the first panel, and wherein the position of the second panel relative to the first panel can be adjusted using the inflatable pouch so as to act as a leverage and/or tilting plane of a video projector.

8. The device according to claim 7, wherein the angle of the second panel relative to the first panel can be adjusted using the inflatable pouch.

9. The device according to claim 8, wherein the first and second panels are connected to each other by an articulation so as to substantially form a V shape whereof the opening angle can be adjusted using the inflatable pouch.

10. The device according to claim 9, wherein the first and second panels are connected to each other, on their periphery, and outside said articulation, by a deformable lateral panel with a bellows function.

11. The device according to claim 5, wherein the first and second panels, and if applicable the deformable lateral panel constitute panels of the leverage bag.

12. The device according to claim 1, further comprising a panel that is mobile and the position of which can be adjusted using the inflatable pouch so as to act as a leverage and/or tilting plane of a video projector.

13. The device according to claim 1, wherein the inflating means can be removed, completely or partially, from the inflatable pouch so as to allow the pouch to be deflated.

14. The device according to claim 1, wherein the inflating means includes an inflating bulb connected to the inflatable pouch by a hose.

15. The device according to claim 13, wherein the hose and/or the inflating bulb can be removed from the inflatable pouch, so as to allow the pouch to be deflated.

16. A video projection assembly according to claim 1, comprising a video projector and an adjustment device.

17. The video projection assembly according to claim 16, wherein the inflating device is placed under the video projector.

18. The video projection assembly according to claim 16, further comprising a carrying case.

19. The video projection assembly according to claim 18, wherein the adjusting device is placed inside the carrying case and can be removed from the carrying case.

20. The video projection assembly according to claim 19, wherein the adjusting device can be implemented with the video projector by being removed from the carrying case.

21. The video projection assembly according to claim 16, further comprising means for fastening making it possible to fasten the adjusting device to the video projector at least during manipulation or transport of the video projection assembly.

22. The video projection assembly according to claim 18, wherein the adjusting device is placed inside the carrying case and is not removable relative to the carrying case.

23. The video projection assembly according to claim 18, wherein the adjusting device is placed inside the carrying case, and can be implemented with the video projector without being taken out of the carrying case.

24. A use of the adjusting device according to claim 1 to adjust the projection angle and/or height of a video projector.
